(19) United States
(12) Patent Application Publication
(10) Pub. No.: US 2011/0199077 A1
(43) Pub. Date: Aug. 18, 2011

(54) FERROUS OBJECT DETECTOR

(76) Inventors: Gary Bergstrom, Moreland Hills, OH (US); Joseph B. Seale, Gorham, ME (US); Nathaniel T. Smith, Gates Mills, OH (US)

(21) Appl. No.: 12/705,919

(22) Filed: Feb. 15, 2010

(51) Int. Cl. G01R 33/10

(52) U.S. Cl. 324/244

(57) ABSTRACT

A three-dimensional magnetic field sensor is used as part of a vehicle detector to monitor plural parking spaces. The detector includes a controller which periodically samples the magnetic field and compares the present field to a prior field. When the difference exceeds a threshold, the change in the field is compared to previously recorded calibration changes to determine which calibration change the present change most closely resembles. The results are displayed to direct customers to vacant parking spaces or to identify spaces which are occupied but whose meters have expired.

### FIELD OF THE DISCLOSURE

The present disclosure relates in general to the detecting ferrous objects, including automobiles.

### BACKGROUND

There has been a long term need for a device and method to detect ferrous objects by monitoring plural spaces for the arrival or departure of an object from the monitored spaces.

### SUMMARY

A method of detecting the presence of a ferrous object in a plurality of monitored spaces comprises the steps of (a) detecting the initial three dimensional magnetic field at a fixed location and in the absence of a ferrous object in any of the spaces to be monitored, (b) performing a calibration by (1) placing a calibration object successively in each of the spaces to be monitored, (2) successively determining a calibration change in the magnetic field at the fixed location from the initial field for each of the monitored spaces when the calibration object is placed successively in each of the monitored spaces and (3) associating each of the successive calibration changes in the magnetic field with the space where the calibration object was when each such change was determined, (c) measuring the three dimensional magnetic field at a first time and at a second time, (d) determining whether the magnetic field has changed from the first time to the second time by finding the difference between the field at the first time and the field at the second time, (e) comparing the difference determined in step (d) to each of the calibration changes to identify the calibration change most like the difference determined in step (d), and identifying the space associated with the identified calibration change, and (f) recording and reporting the identified space.

### DESCRIPTION OF FIGURES

FIG. 1 illustrates a first calibration procedure useful and practicing the method and constructing the apparatus taught by the present disclosure.

FIG. 2 illustrates a first detection sequence useful in practicing the method and constructing the apparatus taught by the present disclosure.

FIG. 3 illustrates a second calibration procedure useful in practicing the method and constructing the apparatus taught by the present disclosure.

FIG. 4 illustrates a second detection sequence useful in practicing the method and constructing the apparatus taught by the present disclosure.

FIG. 5 illustrates a detector constructed according to the teachings of the present disclosure used to detect the presence of an automobile in a parking space and to display the location of available parking spaces.

FIG. 6 illustrates a procedure using two detectors operating on different principles to monitor available parking places.

FIG. 7 illustrates a third calibration procedure useful in practicing the method and constructing the apparatus taught by the present disclosure.

### DETAILED DESCRIPTION

A detector is positioned to detect the presence or absence of a ferrous object in a plurality of positions around the detector. The detector uses a sensor to measure the geomagnetic field in three dimensions. During a calibration step changes in the geomagnetic field are recorded as a test object is placed in each of the positions to be monitored. After calibration the detector takes periodic measurements of the geomagnetic field, comparing the current measurement to a preceding measurement to determine if an object has arrived at or departed from a monitored position. Determination of a change is a two-step process. First the scalar magnitude of the geomagnetic field at time (t) is compared to a subsequent measurement (taken, e.g., at t+1). If that difference exceeds a threshold (set to exclude irrelevant small fluctuations), then the determination proceeds to a second stage.

In the second stage, the vector lying in a horizontal plane and representing the geomagnetic field at time t, V(t), is compared to V(t+1), the vector at t+1. The size and direction of this change indicates how large and, significantly, in what direction from the sensor the change took place. This system can be used to detect any object that disturbs the earth's magnetic field. Using this two-step process enables reliable detection of ferromagnetic objects such as cars and other vehicles. In the calibration step the detector can be set up to monitor changes in two or more nearby locations.

The system and method of detecting ferrous objects can use any commercially available three dimensional low field magnetic sensor, such as, e.g., Honeywell HMC1053 or PNI Micromag. Honeywell has suggested that such sensors may be used to detect the presence of a ferrous object such as an automobile. The inventor is not aware of any successful use of a single one of such a sensor to monitor plural locations for the arrival or departure of ferrous objects. Two approaches are disclosed for using a single three dimensional, low field, magnetic sensor to monitor plural locations. The first is a vector magnitude and two dimensional approach.

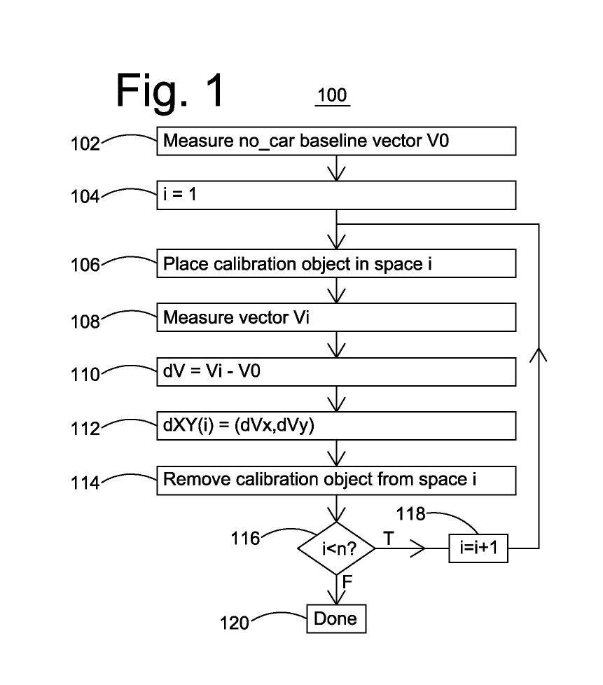

The vector magnitude and two dimensional position approach is illustrated in connection with monitoring two or more parking spaces for the presence of a vehicle, using a single three dimensional magnetic field sensor. The process begins with calibration steps, followed by repeated sequences of detection steps. FIG. 1 shows flowchart 100 with numbered calibration steps.

Beginning with step 102, “Measure no_car baseline vector V0” establishes the prevailing geomagnetic field in the absence of any vehicles. There follows a sequence of calibrating steps, one for each space to be monitored, for example two, in which case the loop limit “n” is set to 2, though this is not limiting. Detection of more than two spaces can be accomplished in the same way. Thus, with step 104, “count i=1”, the count is initialized to calibrate the first space. Step 106 is “Place calibration object in space i”, for example a relatively small vehicle that provides a good directional indication of the middle of the parking space. Step 108 is “Measure vector Vi” for determining the perturbed magnetic field vector with the calibration object occupying space “i”. Step 110 is “dV=Vi−V0” wherein the vector difference dV is computed between the empty-space vector V0 and the vector Vi with a calibration object occupying space number “i”. Step 112 is “dXY(i)=(dVx, dVy)” in which the vertical dVz component of dV is ignored and the 2D field perturbation caused by the calibration object in space (i) in the horizontal (x,y) plane is recorded in a table for future use. The quantity dXY(i) thus represents the change in the magnetic field, viewed in the horizontal plane, caused by the presence of a vehicle in space (i).

Step 114 is “Remove calibration object from space i” in preparation for a possible next step. Step 116 is “i<n?” which tests to see if there is another space to be calibrated. If True, then step 118 “i=i+1” advances the index, and the procedure returns to step 106 with a new space number “i” to calibrate. If test 116 gives a False outcome, then the calibration procedure is “done” in step 120.

When the calibration routine has been completed, the routine has generated a table containing a set of vectors representing the change in the ambient magnetic field when each of the monitored spaces is occupied and the other monitored spaces are empty. In a two-parking space arrangement (n=2), those conditions are: no cars (this is V0); space A occupied, Space B empty; and space A empty, space B occupied. The system does not test every possible combination, so for example there is no vector representing: space A occupied and Space B occupied. When four spaces are monitored, the table includes four entries in addition to the V0 data.

Following the above calibration steps, the object detection steps proceed in flowchart 200 as follows. The purpose of steps 202-213 is to detect whether there has been a change in the filled or empty status (i.e. occupancy status) of a monitored space such as a parking space. At step 202, the program calls up “AbsVsq” from memory. This is the scalar quantity representing the square of the strength of the magnetic field as last measured by the sensor; it represents the state against which the currently measured vector is to be measured to determine whether there has been a change. Immediately after calibration and before any object has occupied a monitored space, “AbsVsq” is based on V0; at a later time after objects have come and gone “AbsVsq” will have some other value based on the most recently measured magnetic field. “AbsVsq” thus serves as a baseline, and its value is the magnitude-squared measure of the vector field strength.

At step 204, “(“dXY0” is previous baseline 2D field vector)” is also called up from memory. This value represents the component of the ambient geomagnetic field vector that lies in the horizontal plane measured, like “AbsVsq”, initially at calibration; at a later time (after objects have come and gone) it will have some other value based on the most recently measured magnetic field. The value of dXY0 is stored for later use. Together “AbsVsq” and “dXY0” represent the three dimensional magnitude-squared and horizontal plane vector components of the magnetic field in the most recent stable state against which the current measurements will be compared to determine whether there has been a change.

The next series of steps determine whether the change in the magnetic field is large enough to merit further examination or is merely noise. At step 206, “Measure magnetic field vector V” establishes a newly-measured 3D magnetic field vector. This vector is the vector to be compared to AbsVsq to determine whether ferrous objects have come or gone since AbsVsq was determined. In step 208, “absVsq=Vx̂2+Vŷ2+Vẑ2” computes and stores the square of the magnitude of the newly-measured vector. In step 210, “DELT=absVsq−AbsVsq” computes and stores the scalar difference between the newly-measured magnitude-squared measurement and the current baseline value. In step 212, “ABS(DELT)<Threshold_{—}0?” asks if the absolute of “DELT” computed step 210 is smaller than a minimum threshold for detection of significant change. If the answer is True, then this detection sequence is “Done” in step 213, and the system waits for a period of time before beginning the sequence of Detection Steps again.

A False result in 212 means the change has exceeded the threshold and leads to a continuing sequence of steps to further analyze the detected change, leading to step 214. In 214, “dxy=(Vx, Vy)−dXY0” computes the 2D vector field difference, in the horizontal (x,y) plane, between the reference vector dXY0 and the vector (Vx, Vy) consisting of the x and y components of the newly-measured magnetic field vector.

Next the procedure prepares a table listing the difference between each of the calibration vectors and the vector dxy calculated in step 214. Each difference is identified by the term “Distance (i)” where “i” is an integer between 1 and n. To this end in step 216, “i=1” sets a counter to go through the spaces from 1 to n, where n is the number of spaces monitored. At step 218, “Distance(i)” is calculated from “Distance(i)=AbsSq(dxy−dXY(i))”. This value is a vector distance-squared comparing the newly-measured 2D vector reading to one of the reference stored calibration readings generated by flowchart 100, step 112. Step 219 calculates the opposite of the vector calculated in step 218. The resulting value is stored in a table.

Step 220, “i<n” checks for completion of the determinations of step 218, with a “not complete” indication of True sending execution to 222, “i=i+1” to increment the index and return execution to 218 for comparison to another stored value “dXY(i)”. When this loop is complete a table has been created which contains 2n entries, each containing a comparison of the change from the previous state to the newly-measured state (1 to n) or a comparison of the opposite of the change from the previous state to the newly-measured state (n+1 to 2n).

When this loop is complete, execution continues with step 224, “MN=MIN(Distance(i))” wherein the minimum value of the values “Distance(i)” is determined. At step 226, “k=(i such that Distance(i)=MN)” identifies the particular index “k” associated with the minimum distance. This minimum corresponds to the newly-measured 2D magnetic vector direction that is closest to one of the calibration vectors from step 112, or to the negative of one of those calibration vectors. A value of k that is between n+1 and 2n means that the monitored space has been vacated, a value of k between 1 and n means the monitored space has been recently occupied. Steps 227-230 perform this test. If k is greater than n, the value of k is reduced by n and the status of monitored space associated with k is set to empty (occupied=false) at steps 228 and 229. If k is less than n, the status of the monitored space corresponding to k is set to “occupied.”

With “k” now identified, step 228, “occ(k)=(SIGN(DELT)<0)” tentatively assigns to space “k” an occupied=True status if DELT was negative, that is, if the magnetic field strength at the sensor was observed to decrease, or otherwise an occupied=False status for a magnitude increase. Step 231 begins an error checking process. First in step 231, “error=(occ(k)==Occ(k))”, it is determined whether the supposedly changed “occupied” status of the identified parking space is in fact unchanged from its earlier status (“Occ(k)”). The “==” or “double equal” symbol is a true-false comparison symbol for equality, as contrasted for the “=” programming symbol for assignment.

Step 231 includes a second consistency check namely occ(k)< >(DELT<0). DELT is the change in the squared length of the magnetic vector. If DELT<0, that means that the new field reading, absVsq, was smaller than the previously stored reference AbsVsq in step 210. That means that, based on field magnitudes (or magnitudes-squared), we expect that the previously empty space has become occupied, with the vehicle drawing magnetic flux into itself and away from the sensor. So a True outcome of “DELT<0” is equivalent to saying that the newly determined, still-tentative value for “occ” should be True. Likewise, a False outcome to “DELT<0” implies that the space has become vacant, which means that “occ” should also be false. The “< >” operator is a “not equal” operator, so that when occ(k) and DELT<0 yield the same result, then the “< >” operator yields False, no error. On the other hand, if “< >” yields True, it means we have an error, and this should force the result of the OR operator to become True as well.

The error value, True or False, from step 231 is checked in step 232, and if True, there is nothing new to report except possibly an error flag because, despite exceeding the threshold for significant changes passed in step 212, in fact, the status of space k had not changed, and the sequence is “Done” at step 234.

The routine that called the sequence 200 will typically involve higher level decisions, for example, to decide whether a vehicle is in the process of parking and is generating an ongoing magnetic signal variation, or if there might be some inconsistency, for example that a long-filled parking space is becoming “more filled” or a long-vacant parking space is becoming “more vacant.” A False reading from 232 means that the new status of space k does represent a change in status from the previously recorded status and sends execution to 236, “Occ(k)=occ(k)” in which the tentative True/False logic status of “occ(k)” is stored in the decided logic status represented by “Occ(k)” using an uppercase rather than lowercase first letter. In step 238, “AbsVsq=absVsq” records the new squared-magnitude of the field strength, which becomes a new reference for detection of change when the steps of 200 are called again from a higher-level program.

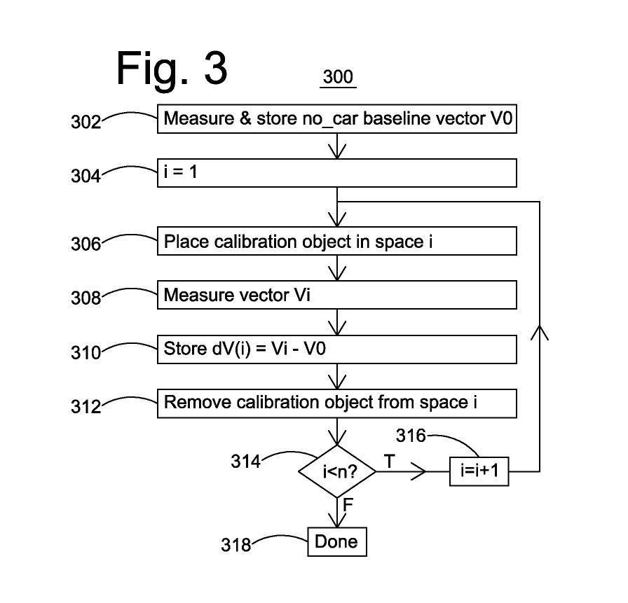

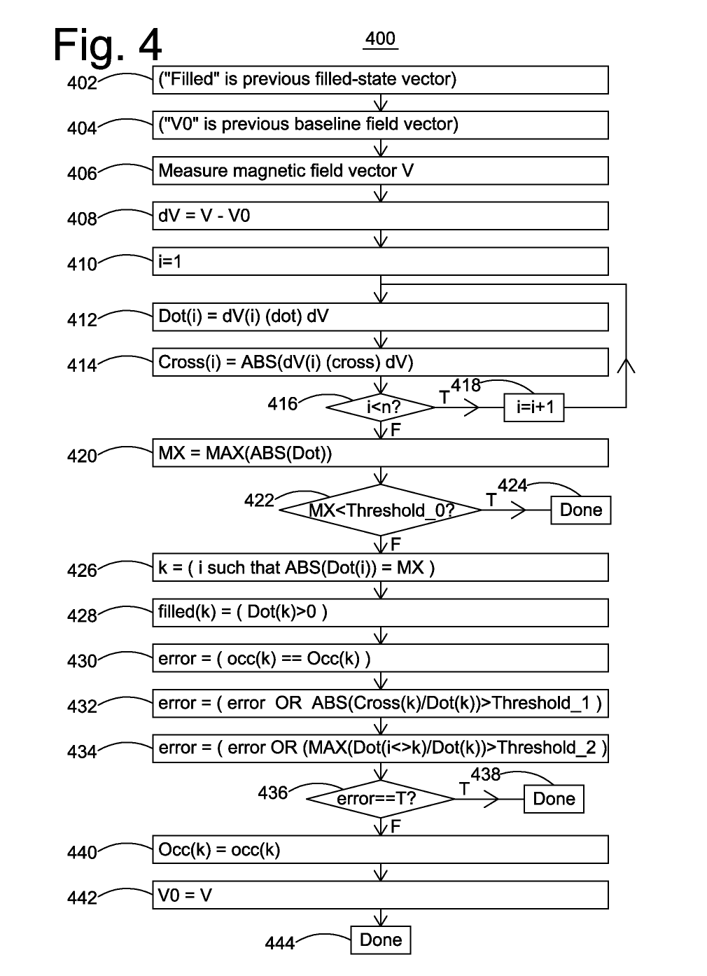

Another pair of calibration steps and detection steps is described in flowcharts 300 and 400 of FIGS. 3 and 4. In calibration steps 300, step 302, “Measure & store no_car baseline vector V0” establishes the 3D magnetic vector reference for the condition where all monitored spaces are empty. Step 304, “i=1” begins stepping through calibration measurements of the two or more parking spaces. Step 306, “Place calibration object in space i” is like step 106 of sequence 100, and similarly for step 308, “Measure vector Vi” compared to step 108. Likewise step 310, “Store dV(i)=Vi−V0” is similar to step 110, but with a small difference in step 310. In step 110, the 3D value “dV” was stored temporarily for computation of a 2D value “dXY(i)” to be stored, whereas in step 310 all three components of the 3D vector “dV(i)” are stored for future reference. Step 312, “Remove calibration object from space i” is like step 114, and similarly for concluding steps 314, 316 and 318 compared to respective steps 116, 118 and 120, either going back to test more parking spaces or finishing with a “Done” step 318.

Following a one-time calibration, the often-repeated detection routine proceeds as illustrated in flowchart 400 of FIG. 4. Preliminary steps 402 and 404, “(“Filled” is previous filled-state vector)” and “(“V0” is previous baseline field vector)” indicate the results of previous detection steps defining the current filled or empty status of each space and the baseline value of the 3D magnetic vector. Then in step 406, “Measure magnetic field vector V” a new vector is measured for processing. In step 408, “dV=V−V0” computes the vector change relative to the baseline. In step 410, “i=1” initiates a loop through the parking space indices, proceeding to 412, “Dot(i)=dV(i) (dot) dV”. Here, the vector operation indicated by “(dot)” is the vector dot product, or inner product, defined as follows. For two vectors, (u,v,w) and (x,y,z), the dot product is given by:

(u,v,w)(dot)(x,y,z)=ux+vy+wz

that is, by the sum of the products of the respective vector components. This product takes on a maximum positive value for vectors of given magnitude that are parallel, a maximum negative value for vectors of given magnitude that are antiparallel, pointing in opposite directions, and a value of zero for vectors that are orthogonal. Step 414, “Cross(i)=ABS(dV(i) (cross) dV)” computes the magnitude of the vector cross product. The cross product itself, a vector quantity, is given by:

(u,v,w)(cross)(x,y,z)=(vz−wy,−uz+wx,uy−vx)

The absolute value “ABS” or magnitude of this vector is the square root of the sum of squares of the vector components, following the Pythagorean Theorem. Computation continues in step 416, “i<n” with a determination if the loop is incomplete, with a True outcome leading to step 418 “i=i+1” where the index is incremented and execution returns to step 412. Otherwise execution continues to step 420, “MX=MAX(ABS(Dot))” in which maximum among the values of Dot(i) from step 412 is assigned to the variable MX. In step 422, “MX<Threshold_{—}0” this MX value is compared to a zeroth threshold magnitude. If MX is smaller than this threshold, then no significant magnetic change is detected, and execution proceeds to step 424, “Done” returning execution control to a higher-level routine that will normally call the detection routine 400 again, repeatedly, at later times.

If a significant change is detected, execution proceeds to step 426, “k=(i such that ABS(Dot(i))=MX)” in which the index i giving the maximum magnitude MX is assigned to “k”. In step 428, “occ(k)=(Dot(k)>0)” a True or False test leads to an assignment to the Boolean variable “occ(k)” being True if the result of the dot product computation from step 412 was positive, i.e. a determination that the measured and reference vectors were pointing generally in the same direction rather than opposite directions.

A True outcome in step 428 tentatively indicates an occupied space, and a False outcome an empty space. In step 430, “error=(occ(k)==Occ(k))”, similar to step 230 of flowchart 200, an error variable is set to True if an already-filled space is apparently re-filled, or an already-empty space is re-emptied. Unlike the following sequence in procedure 200, procedure 400 proceeds with two optional additional steps to detect possible error conditions. In 432, “error=(error OR ABS(Cross(k)/Dot(k))>Threshold_{—}1)” asks if the absolute value of the ratio of the cross product divided by the dot product is larger than a first threshold (“threshold_{—}1”). An unusually large cross product magnitude, compared to the dot product, indicates a significant angle alignment error compared to the reference vector perturbation for an object in the identified space. The Boolean “OR” function combines this outcome with the previous value for “error” so that a True from either input yields a True error output. Step 434, “error=(error OR (MAX(Dot(i< >k)/Dot(k))>Threshold_{—}2))” performs another consistency test for error detection. The values of Dot for all indices “i” excepting for index “k”, which may be just one other index, are compared by ratio to the result for the identified index “k”.

The “MAX” operation here is actually the maximum of the absolute value of the ratio. If this ratio is large, that is if the identification magnitude for space “k” is not much larger than the identification magnitude for a different parking space, “i” not equal to “k”, then there is a high uncertainty in the identification. The resulting “True” outcome of the comparison test is combined with the previous “error” value by the Boolean “OR” function, so that a True outcome from any one of the three optional tests will register as True in step 436, “error==T?” leading to a routine exit at 438, “Done”, along with an error flag that will alert the calling routine to a potential problem.

Optionally, various of the parameters computed in 400 will be made available to the calling routine for further evaluation. If there is no error indication, execution proceeds to 440, “Occ(k)=occ(k)” in which the tentative logic value “occ(k)” for the identified space “k” is assigned to the more permanent “Occ(k)” Boolean variable for that space. In step 442, “V0=V” the most recently measured magnetic vector “V” is assigned as the new baseline reference vector “V0” for detection of further change. Step 442, “Done” completes this routine and flowchart 400.

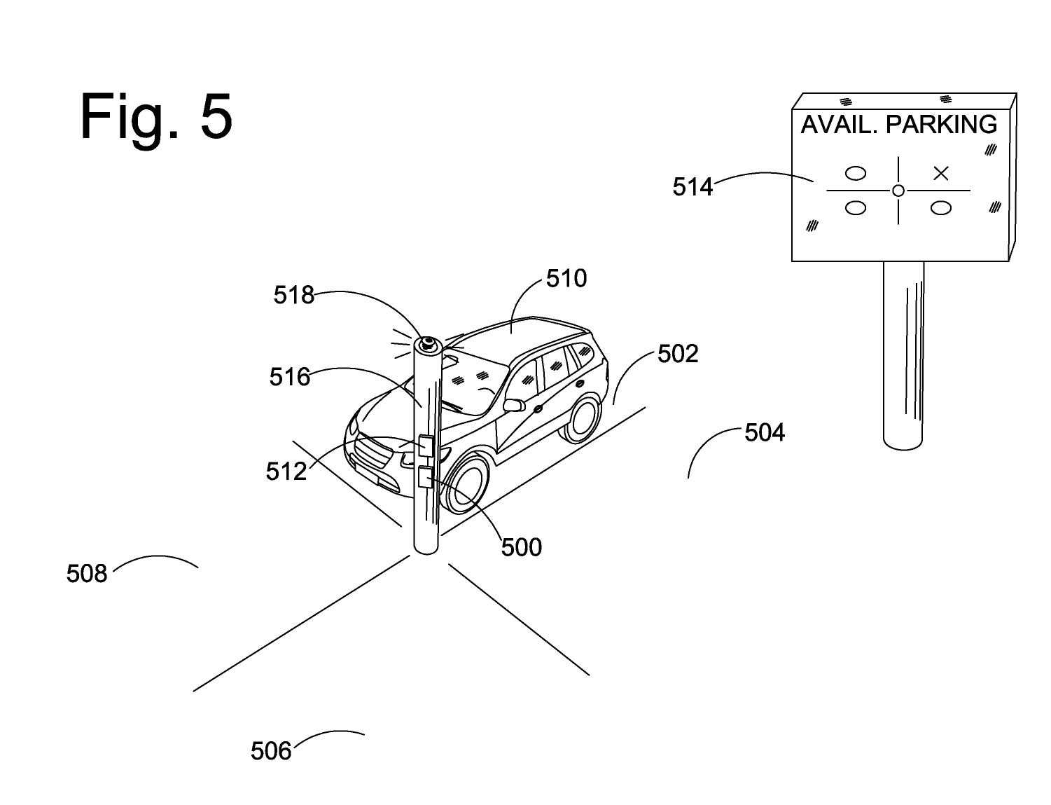

FIG. 5 illustrates an application of the detector 500 described above to sense an automobile in any of four parking spaces. The detector 500 is mounted in a post that is located between four parking spaces 502, 504, 506, and 508 which correspond to n=1-4 in the procedures 100, 200, 300, and 400. The detector 500 may be fitted with and additional sensor 512 which operates on a different principle. Such a detector is illustrated at 512. The detector 512 may be, for example an infra red detector such as are used in camera applications, or a sonar based sensor, or a camera with optical recognition software. The sensor 512 may be called upon only when the procedure 200 or the procedure 400 have generated an error signal, or the sensor 512 may be operative at all times, in parallel with the magnetic sensor within detector 500. In either event, control logic may use the signal from sensor 512 to confirm the status of any of the parking spaces 502-508 or to confirm that the detector is in an error state and requires service.

The signal output from the detector 500 may be used for any of a variety of purposes. For example, when applied to a parking facility, the information about which spaces are occupied and which are empty may be displayed on a sign to direct drivers to unoccupied spaces. This may be particularly important if the bollard 516 in which the detector 500 is mounted also happens to provide facilities not available at all bollards in a parking lot or street, such as vehicle battery recharging services. Instead or in addition to the sign 514, the bollard 516 or post mounting the detector 500 may be equipped with a light 518 positioned to be visible from a distance to help drivers locate an available parking space. The information provided by detector 500 may also be combined with whether a customer has exceeded the parking time purchased to alert law enforcement or a parking lot operator to take necessary action. In addition, the detector 500 with our without additional sensor 516, may be used to detect the presence or absence of ferrous items other than automobiles, such as articles in a warehouse, where a bin or container, itself not ferrous, may carry a magnet so that its presence distorts the earth's magnetic field.

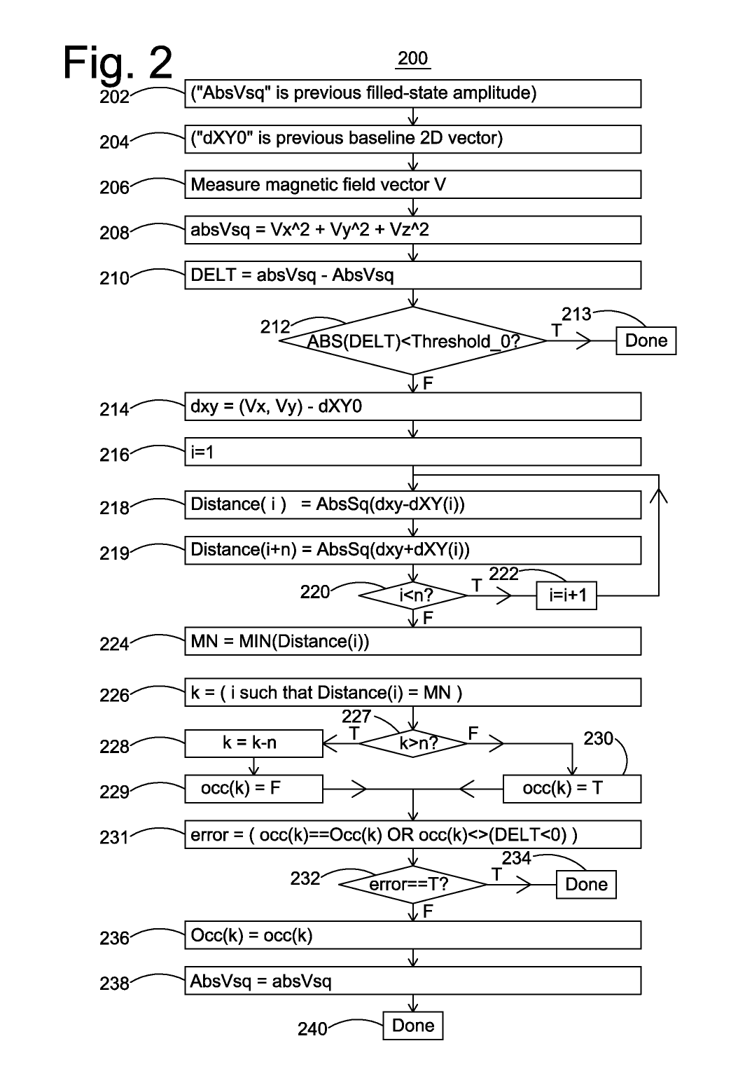

FIGS. 1 and 2 have described calibration steps plus space occupancy detection steps based on a method using a reduction in magnetic field strength to indicate a probable new space occupancy, an increase in magnetic field strength to indicate a probable new space vacancy, and a two-dimensional horizontal-plane vector change analysis to indicate which space has experienced the changed occupancy. FIGS. 3 and 4 have described calibration steps plus space occupancy detection steps based on a method using the magnitude of change of a three-dimensional magnetic vector to indicate a probable change in occupancy of a space, followed by use of the vector dot product and vector cross product to identify which space has experienced the changed occupancy and whether the change was to vacate or to occupy the space. The methods 100 and 200 (FIGS. 1 and 2) assume a geomagnetic field vector that is not too far from vertical, which is the case in locations not too far from the earth's north or south magnetic poles, while the methods 300 and 400 of FIGS. 3 and 4 do not rely on a near-vertical geomagnetic field. A calibration performed for one sensor and an associated set of spaces can be applied to similar sensors and sets of spaces sharing substantially the same geometry and the same angular orientation relative to magnetic north, provided that the commonly-calibrated sets of spaces are not so widely separated or otherwise so magnetically perturbed that the vertical inclination of the geomagnetic field is substantially different for the different sets of spaces.

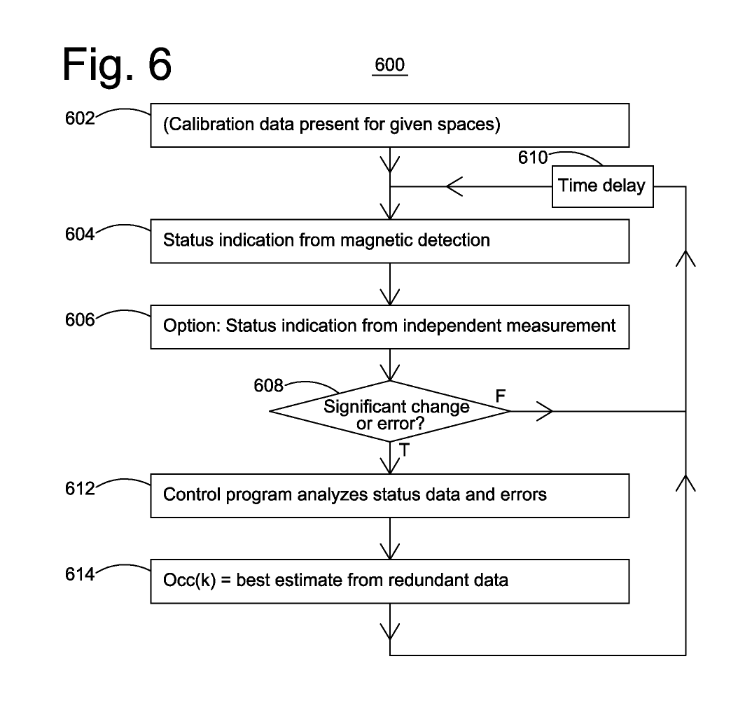

Flowchart 600 of FIG. 6 describes an overview method incorporating the specific steps of 100 and 200, or of 300 and 400, to monitor spaces over time. Step 602, “(Calibration data present for given spaces)”, indicates that preliminary steps as in 100 or 300, or similar calibration steps, are to be performed and the resulting data are to be provided to the procedure of 600. Given that context, step 604, “Status indication from magnetic detection” calls for a procedure such as 200 or 400 or similar to be performed, to produce magnetic change data, possible error flags, and possible conclusions regarding new occupancy or vacancy status.

Step 606, “Option: Status indication from independent measurement” teaches that the system may optionally input and use additional data form independent measurements or sensing means. Such means may include, but are not limited to, optical sensing, infrared sensing (which is particularly sensitive to engine heat from an arriving vehicle), sonar, radar, noise detection and analysis, transponder pinging (as with the transponders otherwise used for automatic toll collection), and mechanical strain sensors that will sense the effects of vehicle weight. Some of these approaches will be too expensive for mass commercialization, others of them good for detecting vehicle presence but not location, and others readily vandalized, for example by placing a piece of tape over the lens of an optical or infrared sensor. Used in conjunction with the processes taught by this disclosure, however, data from one or more secondary measurements can reduce the incidence of errors in the primary magnetic method.

Following step 604 and possibly step 606, if that option is taken, step 608, “Significant change or error” asks if the prior steps report changes or errors that merit further action. If not (a False output), program control proceeds to step 610, “Time delay,” before returning to step 604 for another round. Note that step 610 is optional, in that the loop just described could continue rapidly and uninterrupted until a significant change or error signal arises.

A “True” output from step 608 leads to step 612, “Control program analyzes status data and errors”. Data from intermediate steps in procedures 200 or 400 can be made available to step 612, along with optional independent sensor data from step 606, for the analysis of step 612. Parts of the analysis of step 612 may optionally be incorporated in earlier decision step 608, for example where the system recognizes changing data, such as when a vehicle is parking or leaving or when another vehicle is moving nearby. In such a case, the analysis of step 608 may optionally wait until several consecutive passes through steps 610, 604, 606 and back to 608 have yielded data with little change, indicating a stable situation upon which to base a reliable decision in step 612. The decision output of step 612 is recorded and reported to an external system in step 614, “Filled(k)=best estimate from redundant data”. Such an external system could, for example, be a space vacancy and occupancy display such as display 514 of FIG. 5. Upon completion of step 614, control returns to time delay step 610 for continuation of the monitoring loop.

Given knowledge of the methods and associated apparatus taught here, those skilled in the art will recognize variations on these methods and apparatus. For example, calibration methods 100 and 300 have been described in terms of placement of a ferromagnetic test object sequentially in each of the two or more spaces to be tested. One variation is to place test objects in the spaces in all possible combinations of occupied and empty, record all the results, and base a detection method on this larger data set. Such an approach could better account for nonlinear interactions among ferromagnetic objects, such as vehicles, thus yielding more reliable results from a nonlinear model that characterizes the magnetic field change for a given space while taking into account the effects of objects present or absent in neighboring spaces.

In a second example of alternative calibration methods the calibration of either 100 or 300 could be accomplished mathematically without the use of physical ferrous test objects. It is known that when a magnetically soft ferrous object is placed in an external magnetic field, for example the geomagnetic field, then the external field induces an overall magnetic dipole moment in the ferrous object, along with higher-order multipole moments that depend on the particular shape of the object. The induced dipole moment will be parallel to the inducing external field, and the sensing apparatus taught here measures that inducing external field when vehicles and other ferrous objects are absent. Equations readily found in textbooks or online describe the vector field of a magnetic dipole. It is also known that higher-order multipole moments attenuate with distance more rapidly than the dipole moment, so that the dipole approximation of a complex object generally yields reliable results. Thus, if the locations of the spaces (for example, parking spaces) are known in relation to the sensor apparatus, then the apparatus can self-calibrate by measuring the local geomagnetic field, generating a “virtual ferromagnetic object” whose induced dipole moment is parallel to the measured local geomagnetic field, then “placing” that “virtual object” mathematically at the known coordinates (relative to the sensor location and orientation) of the spaces to be sensed, and computing the directions of magnetic perturbations caused by the presence of that virtual object at the specified location coordinates.

This virtual method can be refined through empirical testing, for example to determine where, within a parking space, best to mathematically place the virtual dipole, in order to minimize the chances of errors in detecting real vehicles having a range of complex shapes and not-centered parking locations. This virtual approach has the advantage of being applicable universally for parking spaces with arbitrary compass orientations over a range of latitudes. Combined with the methodology of procedures 300 and 400, this virtual approach becomes applicable an nearly all latitudes, excepting special cases. An example of a special case is very near the geomagnetic poles, where the near-absence of a horizontal geomagnetic field component will lead to a poor or nonexistent differentiation of location for a sensor that is at the same horizontal level as the ferromagnetic object. Symmetries of this sort, leading to poor or ambiguous readings, can often be avoided, in this case by placing the sensor well above the level of the spaces to be monitored. At non-polar latitudes there will be symmetries that reduce the effectiveness of the procedures taught herein, for example when the magnetic sensor is located between, rather than at the head of, a pair of parking spaces, so that a vehicle centered magnetically due-east of the sensor might cause the same field perturbation as a vehicle centered magnetically due-west of the same sensor. Again, the procedures taught herein can be made to work better by avoiding the offending symmetric sensor placement. An advantage of the “virtual object” calibration approach is that it facilitates identification and avoidance of symmetry situations that would cause problems with detection or discrimination of location as taught in this Specification.

A will be seen from procedures 200 and 400, the method described here relies on the relative independence of magnetic vector changes associated with a new occupancy or new vacancy of a given space, regardless of the occupancy status of adjacent spaces. whether occupied or vacant. Thus, in 200, step 218 provided an array of n values, “Distance(i)” checking for a minimum associated with an occupancy status transition from vacant to occupied, while step 219 extended that array for n additional values, checking for a minimum associated with a status transition from occupied to vacant, where step 219 used the negatives of the calibration changes associated with step 218. Similarly in procedure 400, step 428 determined whether a given dot product was positive or negative, the result of which determined the respective True or False status of the variable “occ(k)”. A reversal of the direction of a vector change causes a reversal of the sign of a dot product, while the absolute value of that dot product is unaffected by the direction reversal. In 400, the sign of the dot product indicated whether the direction of status change was toward “occupied” or toward “vacant.” The fixed occupancy status of other spaces did not matter except for setting the “previous baseline vector” of step 404. Thus, a general calibration procedure will depend only on changes in occupancy status of spaces tested in sequence, and not on the background state of unchanged spaces.

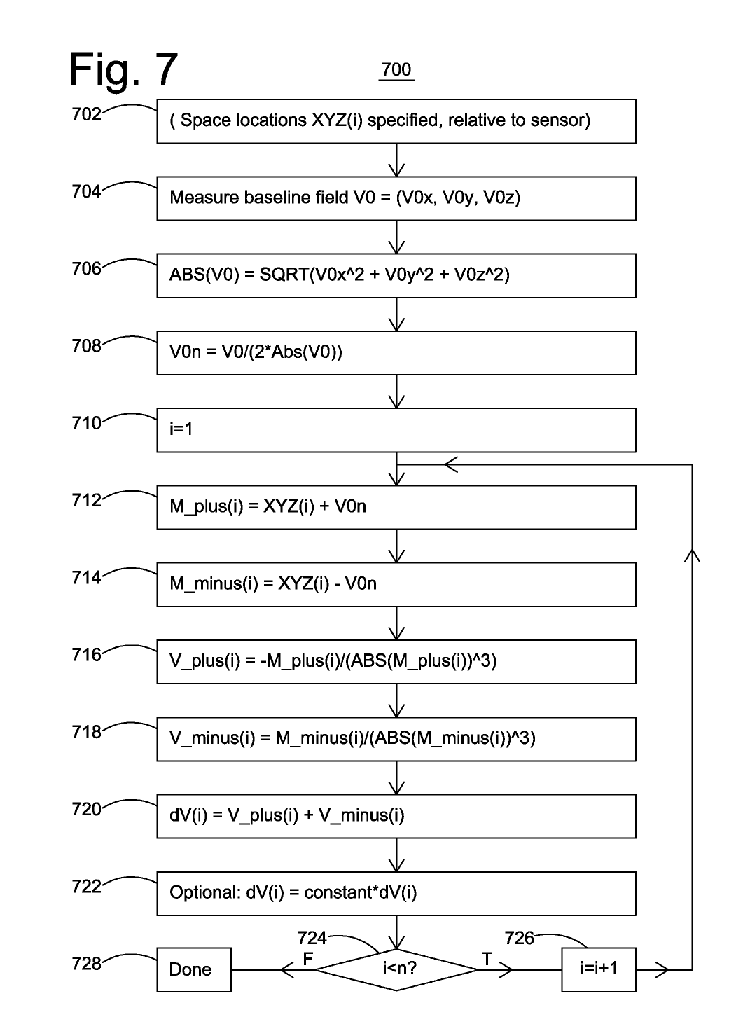

The calibration procedure of either 100 or 300 can be performed entirely mathematically, without the use of physical test objects, except to the extent that a few empirical tests with test objects can be used to fine-tune the mathematical procedure to minimize the chance of detection error. For the purposes of calibration 300, the magnitude of a vector change associated with new-occupancy or new-vacancy of a given space is unimportant, while in calibration 100, the vector changes need to be smaller than the magnitude of the prevailing geomagnetic field so that status transitions toward occupied, when added to the measured field vector, will decrease rather than increase the vector magnitude under conditions described previously. Even though detection magnitudes will differ for spaces at different distances from a detector, little reliance can be placed on vector magnitudes since the sizes of various ferrous objects to be detected, for example vehicles, might vary widely, causing large differences in vector magnitudes having similar directions associated with particular identified spaces. To simplify the vector calculations, the magnetic perturbation field associated with a ferrous object will be modeled not as a mathematical point-dipole (as would be a typical approach taken in theoretical physics), but rather as two point-monopoles separated by a finite distance. To correlate with the actual field perturbation of a “large” object, the separation of the monopoles can be set to the order-of-magnitude of the metallic height (not counting mostly non-metal components such as tires) of an object to be detected, or slightly less than the height to account for rounding of the shape. For simplicity and concreteness of the example, an arbitrary height of one meter will be considered, while distance measurements will be in meters, though this convention is obviously not limiting. Also for convenience, the point monopoles will be of unit strength, meaning that the strength of the vector field associated with a monopole will be just the reciprocal-square of the distance from the monopole, in meters. With these arbitrary conventions, FIG. 7 then describes a self-calibration procedure 700.

In step 702, “(Space locations XYZ(i) specified, relative to sensor)”, the computation system must be supplied with the physical vector locations (x, y, z) of the centers of spaces “i” between 1 and n, relative to the location and spatial orientation of the magnetic sensor. In this example, the unit of distance is taken arbitrarily to be one meter. In step 704, “Measure baseline field V0=(V0x, V0y, V0z)”, the sensor measures the geomagnetic field for empty spaces. This vector field direction is taken to be a good estimate of the field that will induce a dipole moment in a ferrous object in a space, while in practice the local field at various spaces might be perturbed, within limits, by distortions such as ferrous structures no too nearby. In step 706, “ABS(V0)=SQRT(V0x̂2+V0ŷ2+V0ẑ2)” the absolute value, or length, of the vector “V0” is computed as the square root of the sum of squares of the three vector components. In step 708, “V0n=V0/(2*Abs(V0))” a normalized vector “V0n” is defined by dividing the vector quantity V0 by twice the absolute value of the vector as computed in the previous step. This division yields a vector of length one-half. In step 710, “i=1” set an index counter to run through the n spaces, for example, two spaces, or optionally more. In step 712, “Mplus(i)=XYZ(i)+V0n” using vector addition, add the normalized half-unit-length field vector V0n to the location vector XYZ(i) for space number “i”. Similarly in step 714, “M_minus(i)=XYZ(i)−V0n” subtract the normalized field vector V0n from the location vector XYZ(i) for space number “i”. Observe that these resulting two “plus” and “minus” monopole locations are one meter apart, while their line of separation is parallel to the prevailing geomagnetic field and the vector direction going from the monopole “minus” to monopole “plus” is the same as the vector direct ion of the geomagnetic field. In steps 716 and 718, the monopole vector fields are computed, pointing from the objects toward the sensor. Thus in step 716, “V_plus(i)=−M_plus(i)/(ABS(M_plus(i))̂3)”, the minus sign to the right of the equal sign causes the field to point toward the sensor, or in the opposite direction of the vector “M_plus(i)” directed from the sensor to the positive monopole. Division of “M_plus(i)” by “ABS(M_plus(i))” to the first power rather than the third power would result in a vector of unit length in the defined direction. By raising the denominator to the third power rather than the first power, the magnitude of the resulting vector varies inversely as the square of distance, describing a monopole field. Similarly in step 718, “V_minus(i)=M_minus(i)/(ABS(M_minus(i))̂3)” computes a vector associated with the negative monopole, with the opposite polarity of V_plus(i) of step 716, thus explaining the “double reversal” canceling the minus sign of 716 so that there is no minus sign in step 718. In step 720, “dV(i)=V_plus(i)+V_minus(i)”, the two monopole field vector s are summed, giving the field of a dipole with a finite monopole separation, of one meter in this example, though other separation choices are possible, including in a limit process where the monopoles become closer together while their strengths are increased, leading to the description of a point dipole in the mathematical limit. The calibration vector dV(i) of step 720 is useful where only the vector direction matters, as in detection procedure 400, while detection procedure 200 or similar is likely to require a magnitude scale that is realistic in relation to the magnitude of the prevailing geomagnetic field. Where scaling matters, optional step 722 scales each calibration vector dV(i) by a scaling f actor called “constant” that is set to an appropriate magnitude as needed. With or without scaling step 722, execution proceeds to the test step 724, “i<n?”, to determine if there are one or more additional space locations have been calibrated. A True outcome indicates more locations, causing execution to proceed to step 726, “i=i+1”, incrementing the counter, after which execution loops back to step 712. A False result in 724 sends execution to step 728, “Done”, which typically implies a subroutine return to the calling routine, such as the end of step 602 in procedure 600, FIG. 6. The virtual calibration is then complete.

Observe that if one were to set XYZ(i)=(0, 0, 0), thus placing the magnetic sensor midway between the magnetic monopoles, then the positive monopole would be “downstream” of the sensor in relation to the geomagnetic field direction, and the negated vector defined by “V_plus(i)” would point “upstream,” opposing the geomagnetic vector, and similarly for the field from the negative monopole, with no minus sign in the expression of step 718. This is the correct vector direction, because the vector perturbation from the finite-spacing dipole should oppose the prevailing geomagnetic field at the sensor location if the sensor is located between the monopoles or in the equatorial plane equidistant from the two monopoles. If, on the other hand, the sensor were located beyond either end of the spaced monopole pair, on the axis defined by their spacing, then the net effect would be to strengthen the sensor reading. This description provides a check to determine whether the programming of procedure 700 has been done with the correct signs and polarities.

The procedures taught in connection with FIGS. 1-4, 6, and 7 of this disclosure may be embodied in software or code executed by general purpose hardware. As an alternative the procedures (FIGS. 1-4, 6, and 7) may also be embodied in dedicated hardware or a combination of software and general purpose hardware and dedicated hardware. If embodied in dedicated hardware, the procedures (FIGS. 1-4, 6, and 7) can be implemented as a circuit or state machine that employs any one of or a combination of a number of technologies. These technologies may include, but are not limited to, discrete logic circuits having logic gates for implementing various logic functions upon an application of one or more data signals, application specific integrated circuits having appropriate logic gates, programmable gate arrays (PGA), field programmable gate arrays (FPGA), or other components, etc. Such technologies are generally well known by those skilled in the art and, consequently, are not described in detail herein.

The flow charts of FIGS. 1-4, 6, and 7 show the architecture, functionality, and operation of an implementation of the procedures. If embodied in software, each block may represent a module, segment, or portion of code that comprises program instructions to implement the specified logical function(s). The program instructions may be embodied in the form of source code that comprises human-readable statements written in a programming language or machine code that comprises numerical instructions recognizable by a suitable execution system such as a processor in a computer system or other system. The machine code may be converted from the source code, etc. If embodied in hardware, each block may represent a circuit or a number of interconnected circuits to implement the specified logical function(s).

Although the flow charts FIGS. 1-4, 6, and 7 show a specific order of execution, it is understood that the order of execution may differ from that which is depicted. For example, the order of execution of two or more blocks may be scrambled relative to the order shown. Also, two or more blocks shown in succession in FIGS. 1-4, 6, and 7 may be executed concurrently or with partial concurrence. In addition, any number of counters, state variables, warning semaphores, or messages might be added to the logical flow described herein, for purposes of enhanced utility, accounting, performance measurement, or providing troubleshooting aids, etc. Also, the block diagram and/or flow chart of FIG. 1 is relatively self-explanatory and is understood by those with ordinary skill in the art to the extent that software and/or hardware can be created by one with ordinary skill in the art to carry out the various logical functions as described herein.

Also, where the procedures (FIGS. 1-4, 6, and 7) comprise software or code, it can be embodied in any computer-readable medium for use by or in connection with an instruction execution system such as, for example, a processor in a computer system or other system. In this sense, the procedures may comprise, for example, statements including instructions and declarations that can be fetched from the computer-readable medium and executed by the instruction execution system. In the context of the present invention, a “computer-readable medium” can be any medium that can contain, store, or maintain the procedures (FIGS. 1-4, 6, and 7) for use by or in connection with the instruction execution system. The computer readable medium can comprise any one of many physical media such as, for example, electronic, magnetic, optical, electromagnetic, infrared, or semiconductor media. More specific examples of a suitable computer-readable medium would include, but are not limited to, magnetic tapes, magnetic floppy diskettes, magnetic hard drives, or compact discs. Also, the computer-readable medium may be a random access memory (RAM) including, for example, static random access memory (SRAM) and dynamic random access memory (DRAM), or magnetic random access memory (MRAM). In addition, the computer-readable medium may be a read-only memory (ROM), a programmable read-only memory (PROM), an erasable programmable read-only memory (EPROM), an electrically erasable programmable read-only memory (EEPROM), or other type of memory device.

What is claimed is:

1. A method of detecting the presence of a ferrous object in a plurality of monitored spaces comprising the steps of
(a) detecting the initial three dimensional magnetic field at a fixed location and in the absence of a ferrous object in any of the spaces to be monitored,
(b) performing a calibration by (1) placing a calibration object successively in each of the spaces to be monitored, (2) successively determining a calibration change in the magnetic field at the fixed location from the initial field for each of the monitored spaces when the calibration object is placed successively in each of the monitored spaces and (3) associating each of the successive calibration changes in the magnetic field with the space where the calibration object was when each such change was determined, (dependent claim—recording the 2d change by each)
(c) measuring the three dimensional magnetic field at a first time and at a second time,
(d) determining whether the magnetic field has changed from the first time to the second time by finding the difference between the field at the first time and the field at the second time,
(e) comparing the difference determined in step (d) to each of the calibration changes to identify the calibration change most like the difference determined in step (d), and identifying the space associated with the identified calibration change, and
(f) recording and reporting the identified space.

2. The method of claim 1 where in the step of successively determining a calibration change for each of the monitored spaces includes the step of determining the horizontal plane components of the calibration change for each successive space.

3. The method of claim 2 wherein the step of comparing the difference determined in step (d) includes comparing the horizontal plane components of the difference determined in step (d) with the horizontal plane components of the calibration change for each successive space.

4. The method of claim 3 wherein the step of comparing horizontal plane components of the difference determined in step (d) with the horizontal plane components of the calibration change for each successive space includes comparing the sum of the squares of x and y components of the difference determined in step (d) with the sum of the squares of x and y components of each of the calibration changes.

5. The method of claim 1 further including determining whether the scalar magnitude of the difference determined in step (d) exceeds a threshold value.

6. The method of claim 1 where in the step of comparing the difference between the difference determined in step (d) to each of the calibration changes includes determining the dot product of the difference determined in step 4 and the calibration change associated with each of the spaces.

7. The method of claim 1 where in the monitored spaces are spaces proportioned to fit motor vehicles.

8. The method of claim 7 wherein the step of recording and reporting the identified space includes displaying the identity of spaces that are free of motor vehicles.

9. The method of claim 7 further including providing a second sensor positioned to monitor the presence or absence of an automobile in at least one of the monitored spaces and the step of recording and reporting the identified spaced includes recording signals from the second sensor.

10. A parking space monitor for monitoring the status of a plurality of parking spaces, said monitor comprising a sensor generating signals responsive to the earth's magnetic field for measuring the magnetic field at a selected position, a controller connected to the sensor for processing the signals generated by the sensor, and a display connected to the controller for presenting information concerning the status of the monitored plurality of parking spaces, the processor
(a) receiving a measurement of an initial three dimensional magnetic field at the selected position and in the absence of a ferrous object in any of the spaces to be monitored,
(b) recording a calibration change for each of the monitored spaces generated by (1) a calibration object successively placed in each of the spaces to be monitored, (2) successively determining a calibration change in the magnetic field at the selected position from the initial field for each of the monitored spaces when the calibration object is placed successively in each of the monitored spaces and (3) associating each of the successive calibration changes in the magnetic field with the space where the calibration object was when each such change was determined
(c) measuring the three dimensional magnetic field at a first time and at a second time,
(d) determining whether the magnetic field has changed from the first time to the second time by finding the difference between the field at the first time and the field at the second time,
(e) comparing the difference determined in step (d) to each of the calibration changes to identify the calibration change most like the difference determined in step (d), and identifying the space associated with the identified calibration change, and
(f) recording and reporting the identified space.

11. The parking space monitor of claim 10 where in the step of recording a calibration change for each of the monitored spaces includes the step of determining the horizontal plane components of the calibration change for each successive monitored space.

12. The method of claim 11 wherein the step of comparing the difference determined in step (d) includes comparing the horizontal plane components of the difference determined in step (d) with the horizontal plane components of the calibration change for each successive space.

13. The method of claim 12 wherein the step of comparing horizontal plane components of the difference determined in step (d) with the horizontal plane components of the calibration change for each successive space includes comparing the sum of the squares of x and y components of the difference determined in step (d) with the sum of the squares of x and y components of each of the calibration changes.

14. The parking space monitor of claim 10 where in the processor determines whether the scalar magnitude of the difference determined in step (d) exceeds a threshold value.

15. The parking space monitor of claim 10 where in the step of comparing the difference between the difference determined in step (d) to each of the calibration changes includes determining the dot product of the difference determined in step (d) and the calibration change associated with each of the monitored parking spaces.

16. The parking space monitor of claim 10 further including a second sensor positioned to monitor the presence or absence of an automobile in at least one of the monitored spaces and the step of recording and reporting the identified spaced includes recording signals from the second sensor.

16. A method of detecting whether each of a plurality of monitored spaces is either vacant or occupied by a ferrous object, comprising the steps of
(a) detecting the three dimensional magnetic field at a fixed location,
(b) performing a calibration by (1) employing at least one calibration object, where each monitored space can have an occupancy status of either vacant or occupied by a calibration object, (2) using the at least one calibration object to cause changes in the occupancy status of the spaces, (3) determining calibration changes in the detected magnetic field associated with the changes in occupancy status, (4) correcting the sign of the calibration changes by multiplying calibration changes by minus one where the calibration changes are associated with a status change from occupied to vacant, (5) continuing steps 2 through 4 until calibration changes, with associated sign reversals, have been recorded for all the monitored spaces, (6) associating the sign-corrected magnetic calibration changes with the corresponding monitored spaces and with occupied status, (7) defining a calibration set that includes the sign-corrected calibration changes of step 6 along with the associated corresponding spaces and occupancy statuses for all members of the calibration set;
(c) measuring the three dimensional magnetic field at a first time and at a second time,
(d) determining whether the magnetic field has changed from the first time to the second time by finding the difference between the field at the first time and the field at the second time,
(e) comparing the difference determined in step (d) sequentially to each of the calibration set members to identify the calibration change most like the difference determined in step (d), and identifying the corresponding space and occupancy status associated with the identified calibration set member, and
(f) recording and reporting the identified space and its occupancy status

17. The method of claim 16 wherein the calibration steps further include steps of (1) associating the negatives of the sign-corrected magnetic calibration changes with the corresponding monitored spaces and with vacant status, and (2) including in the calibration set the negatives of the sign-corrected calibration changes.

18. The method of claim 16 wherein the calibration object is a physical ferrous object.

19. The method of claim 16 wherein the calibration object is a computed virtual object associated with coordinates relative to said fixed location, the coordinates corresponding to the plurality of monitored spaces, and wherein computed magnetic dipoles are associated with the virtual objects, those dipoles being aligned to a geomagnetic field determined physically by said detecting, and wherein said step of determining calibration changes includes computing the magnetic field vectors of said computed magnetic dipoles at the fixed location of detecting.

20. The method of claim 14, wherein the step of determining whether the magnetic field has changed includes determining whether a measure of the magnitude of the magnetic field has changed, and the step of comparing the difference between first and second times to calibration set members includes comparing horizontal-plane vector magnetic differences.

21. The method in claim 20 further comprising one or more error checking steps from among the steps of:
(a) associating a decreasing measure of magnitude with a tentative new occupied status, an increasing measure of magnitude with a tentative new vacant status, and determining a True error status if the tentative new occupied or vacant status is different from the occupancy status associated with the calibration set member,
(b) determining a True error status if a newly-determined occupancy status, associated with a change in measured magnitude that exceeds a predetermined threshold, is the same occupancy status as the most recent previously-recorded occupancy status for the same identified space.

22. The method of claim 16 wherein said identifying the calibration change most like the difference in step (d) consists of computing the dot products of the difference in step (d) with each of the calibration changes in the set, identifying the largest of the dot products, and associating that largest dot product with the identified calibration change and associated calibration set member.

23. The method of claim 22, further including one or more error-checking steps from among the steps of:
(a) determining a True error status if a newly-determined occupancy status, associated with a measured 3D magnetic field change that exceeds a predetermined threshold, is the same occupancy status as the most recent previously-recorded occupancy status for the same identified space,
(b) determining a True error status by computing the magnitude of the cross product of the same vector components that determined the largest dot product, computing the ratio of that cross product magnitude to the largest dot product magnitude, and determining that the resulting ratio exceeds a predetermined first threshold
(c) determining a True error status by computing the ratio of the second-largest dot product divided by the largest dot product, and determining that the resulting ratio exceeds a predetermined second threshold.
